(19) United States
(12) Patent Application Publication
(10) Pub. No.: US 2008/0150022 A1
(43) Pub. Date: Jun. 26, 2008

(54) POWER TRANSISTOR FEATURING A VARIABLE TOPOLOGY LAYOUT

(75) Inventors: Robert A. Pryor, Mesa, AZ (US); Gabriele F. Formicone, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC., Austin, TX (US)

(21) Appl. No.: 11/961,426

(22) Filed: Dec. 20, 2007

Related U.S. Application Data
(60) Provisional application No. 60/871,115, filed on Dec. 20, 2006.

(51) Int. Cl. H01L 21/336; H01L 29/78

(52) U.S. Cl. 257/341; 438/286; 257/E29.256; 257/E21.417

(57) ABSTRACT

A power transistor comprises a number of groups of gate fingers of various widths and can include uniform or non-uniform pitch. The widths may include any number of different widths. In one embodiment, there are included three widths W₁, W₂, and W₃, in which W₃>W₂>W₁. The groups of gate fingers are arranged from greater width to lesser width disposed from a periphery to a center of the device. In addition, the gate fingers are configured to have one of a centered justification, a gate pad side justification, and a drain pad side justification, along a dimension of the power transistor layout. In another embodiment, the groups of gate fingers having widths W₁, W₂, and W₃ are configured symmetrically about a center line of the device. The variable gate finger widths provide a level of greater power density at the outside of the die in relation to a power density at the center of the die. Asymmetrical arrangements of gate finger widths are also contemplated.

### CROSS-REFERENCE TO CO-PENDING APPLICATION

This application claims priority to provisional patent application Ser. No. 60/871,115 entitled “POWER TRANSISTOR FEATURING A VARIABLE TOPOLOGY LAYOUT,” filed on Dec. 20, 2006, and assigned to the assignee of the present application.

### BACKGROUND

1. Field

This disclosure relates generally to RF devices, and more specifically, to an RF power transistor featuring a variable topology layout and method thereof.

2. Related Art

Large periphery radio frequency (RF) power transistors known in the art, such as, laterally diffused metal oxide semiconductor (LDMOS) transistor devices, suffer from inadequate RF feeding, RF loading and RF power extraction.

Accordingly, there exists a need for improved RF feeding, loading and power extraction, in particular, for large periphery RF power transistors, such as LDMOS devices.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a layout view of a power transistor with gate fingers of uniform width on the order of 500 μm, having uniform pitch;

FIG. 2 is a layout view of a power transistor with gate fingers of uniform width on the order of 500 μm, having provision for widths as great as 750 μm, and having uniform pitch;

FIG. 3 is a layout view of a power transistor with groups of gate fingers of uniform width and variable pitch of 20 μm, 40 μm, and 60 μm from a periphery to a center of the device;

FIG. 4 is a layout view of a power transistor with groups of gate fingers of uniform width and variable pitch of 60 μm, 40 μm, and 20 μm from a periphery to a center of the device;

FIG. 5 is a layout view of a power transistor according to one embodiment of the present disclosure, the transistor comprising groups of gate fingers of various widths and uniform pitch, wherein gate fingers of greater width to lesser width are disposed from a periphery to a center of the device, and the gate fingers further having a centered justification along a dimension of the power transistor layout;

FIG. 6 is a layout view of a power transistor, the transistor comprising groups of gate fingers of various widths and uniform pitch, wherein gate fingers of lesser width to greater width are disposed from a periphery to a center of the device, and the gate fingers further having a centered justification along a dimension of the power transistor layout;

FIG. 7 is a layout view of a power transistor according to another embodiment of the present disclosure, the transistor comprising groups of gate fingers of various widths and uniform pitch, wherein gate fingers of greater width to lesser width are disposed from a periphery to a center of the device, and the gate fingers further having a gate pad side justification along a dimension of the power transistor layout;

FIG. 8 is a layout view of a power transistor, the transistor comprising groups of gate fingers of various widths and uniform pitch, wherein gate fingers of lesser width to greater width are disposed from a periphery to a center of the device, and the gate fingers further having a gate pad side justification along a dimension of the power transistor layout;

FIG. 9 is a layout view of a power transistor according to another embodiment of the present disclosure, the transistor comprising groups of gate fingers of various widths and uniform pitch, wherein gate fingers of greater width to lesser width are disposed from a periphery to a center of the device, and the gate fingers further having a drain pad side justification along a dimension of the power transistor layout;

FIG. 10 is a layout view of a power transistor, the transistor comprising groups of gate fingers of various widths and uniform pitch, wherein gate fingers of lesser width to greater width are disposed from a periphery to a center of the device, and the gate fingers further having a drain pad side justification along a dimension of the power transistor layout;

FIG. 11 is a graphical view of RF performance characteristics for transistors having layouts of FIGS. 2-10; and

FIG. 12 is a table view of RF performance characteristics for a number of transistors having layouts of FIGS. 2-10.

### DETAILED DESCRIPTION

As described herein, semiconductor substrate can be any semiconductor material or combinations of materials, such as gallium nitride, gallium arsenide, silicon germanium, silicon-on-insulator (SOI), silicon, monocrystalline silicon, the like, and combinations of the above.

According to the embodiments of the present disclosure, an RF transistor comprises a layout configured with a variable component finger size and/or spacing such that more power and/or power density is obtained on the outside of the die than in the center of the die. This is in contrast to currently available RF transistors that have a uniform, repetitive layout of same size transistor fingers. An RF field effect transistor can include a plurality of unit cells electrically connected in parallel, each unit cell having a source region and a drain region. A plurality of gates of the unit cells is also provided. The each gate of the plurality of gates is electrically connected in parallel.

RF transistors, and in particular, high power RF transistors, known in the art presently comprise multiple replications of same size individual transistor “fingers”. These multiple fingers must be driven with a common RF signal. Power from each of the multiple fingers must be summed to provide the total transistor power output. It is noted that as total effective gate width (e.g., for field effect transistors (FETs)) becomes larger, actual total power delivered from the whole may not be as much as the sum of the parts (i.e., the sum of the individual replicated fingers). This effect may be related to one or more of (i) impedance matching between fingers, (ii) transmission line effects in paralleling the fingers, and (iii) electromagnetic interaction effects when collections of fingers are in proximity to one another.

In connection with the embodiments of the present disclosure, an empirical study has been performed using a specifically designed test mask to evaluate the effect of various layout topologies for large transistors. For the study, the fingers of variable gate width and spacing (e.g., pitch) have been combined in an unusual fashion. The outcome of the study revealed that a variable layout topology for individual fingers, which creates greater power density at the outside of the die in relation to the center of the die, exhibits significantly improved RF performance metrics over a conventionally designed, uniformly distributed finger layout. In addition, the variable layout topology further exhibits improved RF performance over an inverse design where more power is distributed to the center of the die than to the edges.

The embodiments of the present disclosure provide several designs that are applicable to LDMOS transistors, as well as to RF power transistors, where improved performance is desired to be obtained. The embodiments include using fingers of variable width, with the widest portions of the plurality of fingers located at the sides and the narrowest portions of the plurality of fingers located proximate the center of the die. In another embodiment, the layout includes the use of fingers of the same and/or different width but with variable pitch, with the smallest pitch (closest spacing) proximate the sides of the die and the largest pitch (widest spacing) proximate the center of the die. The embodiments of the present disclosure further include combinations and variations of the same.

Accordingly, the embodiments of the present disclosure resolve problems in the art by reducing performance losses as overall RF transistor size becomes larger. As a result, the net effect is the same as improving the technical performance of existing RF transistor finger elements. Accordingly, the layout geometry according to the embodiments of the present disclosure can provide improved transistor performance (corresponding to a relatively low cost solution) that must otherwise come from intrinsic transistor processing improvements (corresponding to a solution that is relatively at much higher cost).

The embodiments of the present disclosure can also be integrated into multiple-die packaged component parts. Such parts can include internal input and output impedance matching circuits. In addition, the embodiments of the present disclosure may be applied as a next generation technology platform for LDMOS RF power amplifier (PA) product lines. Such product lines may include, but not be limited to, PA families for wireless (cellular) infrastructure. In addition, the embodiments of the present disclosure provide for a “next generation” RF power transistor device performance.

As discussed herein, the embodiments of the present disclosure provide for improved RF feeding, loading and power extraction for large periphery RF power transistors, such as LDMOS devices.

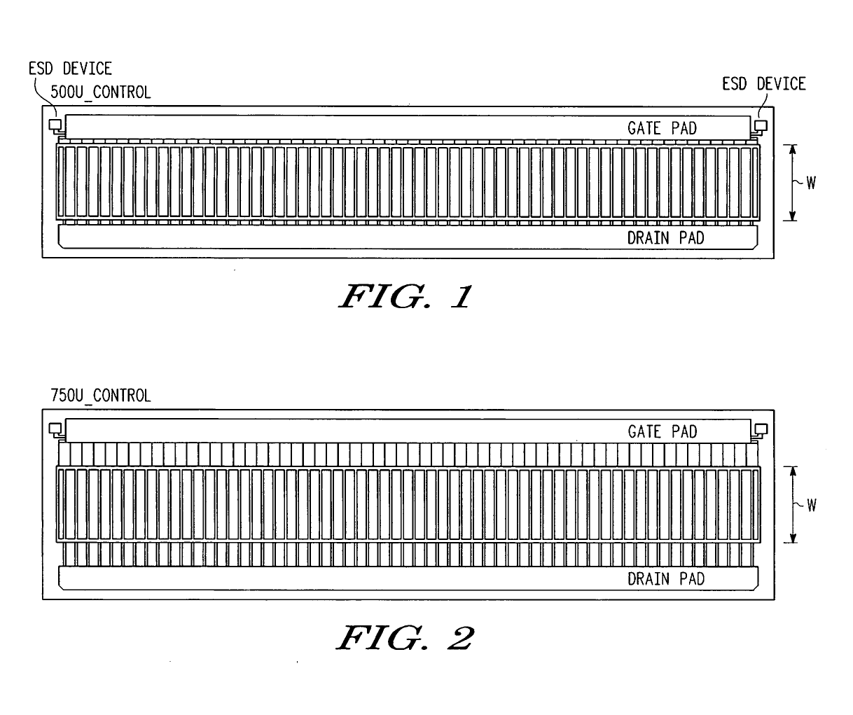

FIG. 1 is a layout view of a power transistor with gate fingers of uniform width on the order of 500 μm. FIG. 2 is a layout view of a power transistor with gate fingers of uniform width on the order of 500 μm with provision for widths as great as 750 μm. As discussed herein, such transistor layouts suffer from inadequate RF feeding (power input), RF loading, and RF power extraction (power output).

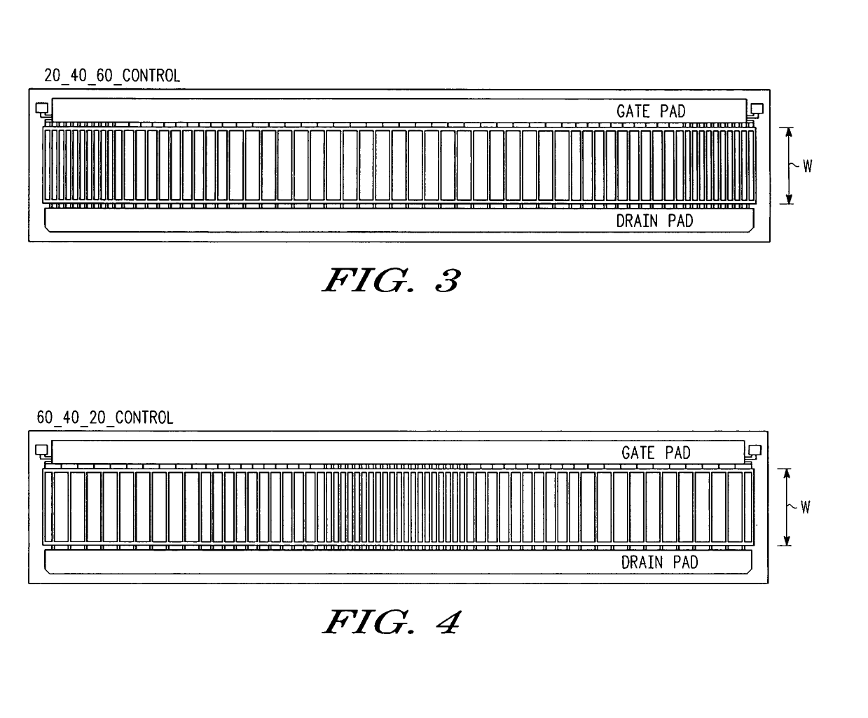

FIG. 3 is a layout view of a power transistor with groups of gate fingers of uniform width and variable pitch of 20 μm, 40 μm, and 60 μm from a periphery to a center of the device. FIG. 4 is a layout view of a power transistor with groups of gate fingers of uniform width and variable pitch of 60 μm, 40 μm, and 20 μm from a periphery to a center of the device. The embodiment of FIG. 3 utilizes variable pitch to provide a level of greater power density at the outside of the die in relation to the center of the die, whereas the embodiment of FIG. 4 utilizes variable pitch to provide a level of lesser power density at the outside of the die in relation to the center of the die.

FIG. 5 is a layout view of a power transistor according to one embodiment of the present disclosure. The transistor comprises a number of groups of gate fingers of various widths and uniform pitch. For example, the widths may include any number of different widths. As illustrated, the embodiment includes three widths W₁, W₂, and W₃, in which W₃>W₂>W₁. Further with respect to this embodiment, the groups of gate fingers are arranged from greater width to lesser width disposed from a periphery to a center of the device. In addition, with respect to the embodiment of FIG. 5, the gate fingers are configured to have a centered justification along a dimension of the power transistor layout.

FIG. 5 illustrates a first center line C_{L(1)} along a first dimension of the device layout and a second center line C_{L(2)} along a second dimension of the device layout. As illustrated, the groups of gate fingers having widths W₁, W₂, and W₃ are configured symmetrically about the second center line C_{L(2)}. The embodiment of FIG. 5 utilizes variable gate finger width for providing a level of greater power density at the outside of the die in relation to a power density at the center of the die. Asymmetrical arrangements of gate finger widths are also contemplated.

While the embodiment of FIG. 5 illustrates gate fingers having uniform pitch, it is noted that the pitch of the respective groups of gate fingers may also be varied. That is, the groups of gate fingers of variable width can be configured to have variable pitch of 20 μm, 40 μm, and 60 μm from a periphery to a center of the device. In another embodiment, the groups of gate fingers of variable width can be configured to have variable pitch from a first pitch value to a second pitch value, wherein the first pitch value is smaller than the second pitch value, extending from a periphery to a center of the device.

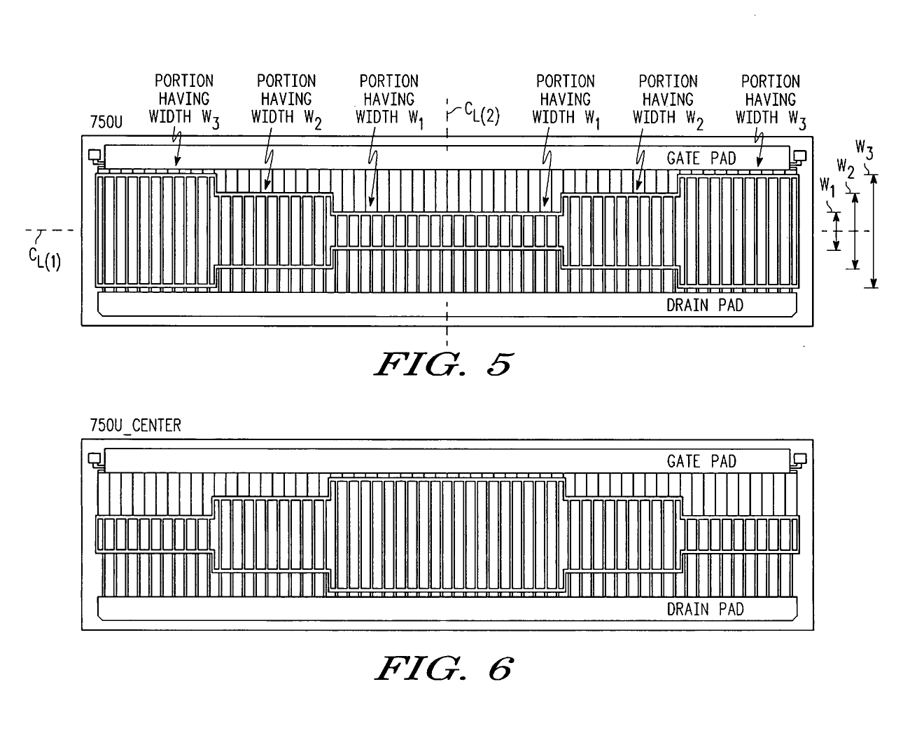

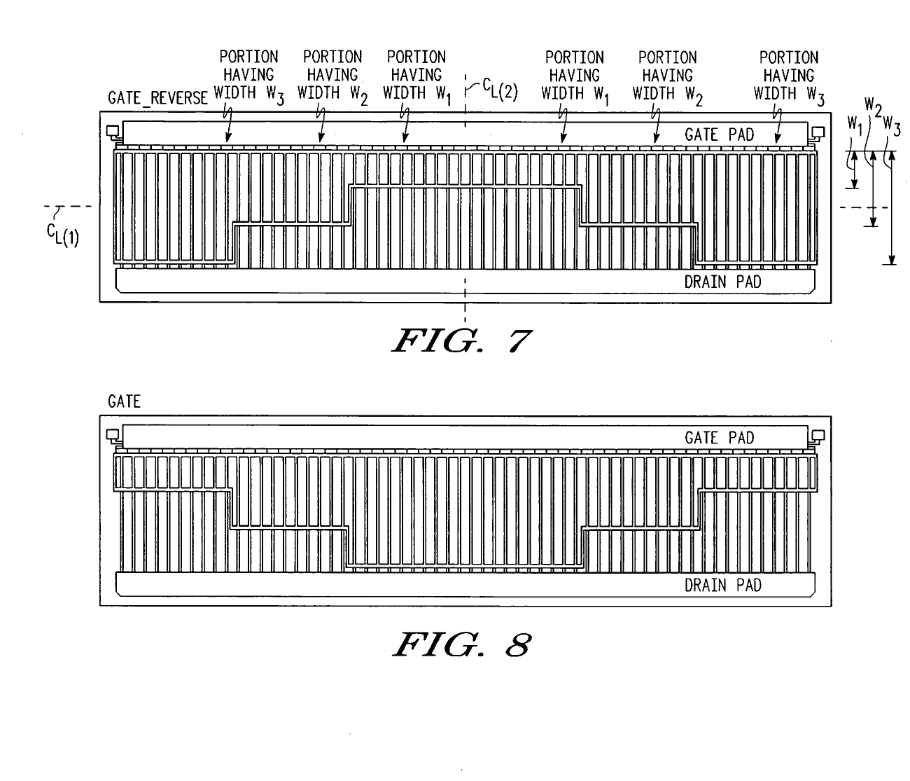

FIG. 6 is a layout view of a power transistor, the transistor comprising groups of gate fingers of various widths and uniform pitch, wherein gate fingers of lesser width to greater width are disposed from a periphery to a center of the device. In the transistor layout of FIG. 6, the gate fingers further have a centered justification along a dimension of the power transistor layout. However, the embodiment of FIG. 6 utilizes variable gate finger width to provide a level of lesser power density at the outside of the die in relation to the center of the die.

FIG. 7 is a layout view of a power transistor according to another embodiment of the present disclosure. The transistor comprises groups of gate fingers of various widths and uniform pitch. For example, the widths may include any number of different widths. As illustrated, the embodiment includes three widths W₁, W₂, and W₃, in which W₃>W₂>W₁. Further with respect to this embodiment, the groups of gate fingers are arranged from greater width to lesser width disposed from a periphery to a center of the device. In addition, with respect to the embodiment of FIG. 7, the gate fingers are configured to have a gate pad side justification along a dimension of the power transistor layout. FIG. 7 illustrates a first center line C_{L(1)} along a first dimension of the device layout and a second center line C_{L(2)} along a second dimension of the device layout. As illustrated, the groups of gate fingers having widths W₁, W₂, and W₃ are configured symmetrically about the second center line C_{L(2)}. The embodiment of FIG. 7 utilizes variable gate finger width for providing a level of greater power density at the outside of the die in relation to a power density at the center of the die. Asymmetrical arrangements of gate finger widths are also contemplated.

While the embodiment of FIG. 7 illustrates gate fingers having uniform pitch, it is noted that the pitch of the respective groups of gate fingers may also be varied. That is, the groups of gate fingers of variable width can be configured to have variable pitch of 20 μm, 40 μm, and 60 μm from a periphery to a center of the device. In another embodiment, the groups of gate fingers of variable width can be configured to have variable pitch from a first pitch value to a second pitch value, wherein the first pitch value is smaller than the second pitch value, extending from a periphery to a center of the device.

FIG. 8 is a layout view of a power transistor, the transistor comprising groups of gate fingers of various widths and uniform pitch, wherein gate fingers of lesser width to greater width are disposed from a periphery to a center of the device. In the transistor layout of FIG. 8, the gate fingers further have a gate pad side justification along a dimension of the power transistor layout. However, the embodiment of FIG. 8 utilizes variable gate finger width to provide a level of lesser power density at the outside of the die in relation to the center of the die.

FIG. 9 is a layout view of a power transistor according to another embodiment of the present disclosure. The transistor comprises groups of gate fingers of various widths and uniform pitch. For example, the widths may include any number of different widths. As illustrated, the embodiment includes three widths W₁, W₂, and W₃, in which W₃>W₂>W₁. Further with respect to this embodiment, the groups of gate fingers are arranged from greater width to lesser width disposed from a periphery to a center of the device. In addition, with respect to the embodiment of FIG. 9, the gate fingers are configured to have a drain pad side justification along a dimension of the power transistor layout. FIG. 9 illustrates a first center line C_{L(1)} along a first dimension of the device layout and a second center line C_{L(2)} along a second dimension of the device layout. As illustrated, the groups of gate fingers having widths W₁, W₂, and W₃ are configured symmetrically about the second center line C_{L(2)}. The embodiment of FIG. 9 utilizes variable gate finger width for providing a level of greater power density at the outside of the die in relation to a power density at the center of the die. Asymmetrical arrangements of gate finger widths are also contemplated.

While the embodiment of FIG. 9 illustrates gate fingers having uniform pitch, it is noted that the pitch of the respective groups of gate fingers may also be varied. That is, the groups of gate fingers of variable width can be configured to have variable pitch of 20 μm, 40 μm, and 60 μm from a periphery to a center of the device. In another embodiment, the groups of gate fingers of variable width can be configured to have variable pitch from a first pitch value to a second pitch value, wherein the first pitch value is smaller than the second pitch value, extending from a periphery to a center of the device.

In addition to the above, with respect to the embodiments of FIGS. 5, 7, and 9, each group of gate fingers can comprise any number of gate fingers of a given width within a corresponding group. The portions of the layout having different widths can each include a same number or different numbers of gate fingers. For example, a first group of gate fingers having a first width can include a first number of gate fingers, whereas a second group of gate fingers can include a second number of gate fingers. The second number of gate fingers may or may not be the same as the first number of gate fingers. In addition, in this example, the second width may or may not be different from the first width.

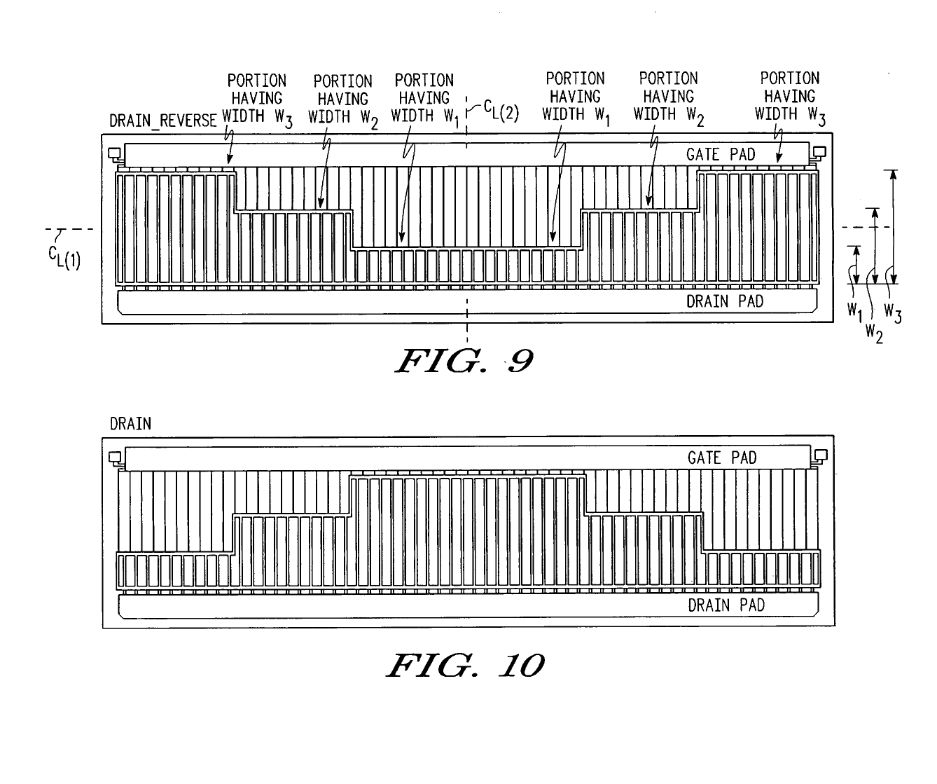

FIG. 10 is a layout view of a power transistor, the transistor comprising groups of gate fingers of various widths and uniform pitch, wherein gate fingers of lesser width to greater width are disposed from a periphery to a center of the device. In the transistor layout of FIG. 10, the gate fingers further have a drain pad side justification along a dimension of the power transistor layout. However, the embodiment of FIG. 10 utilizes variable gate finger width to provide a level of lesser power density at the outside of the die in relation to the center of the die.

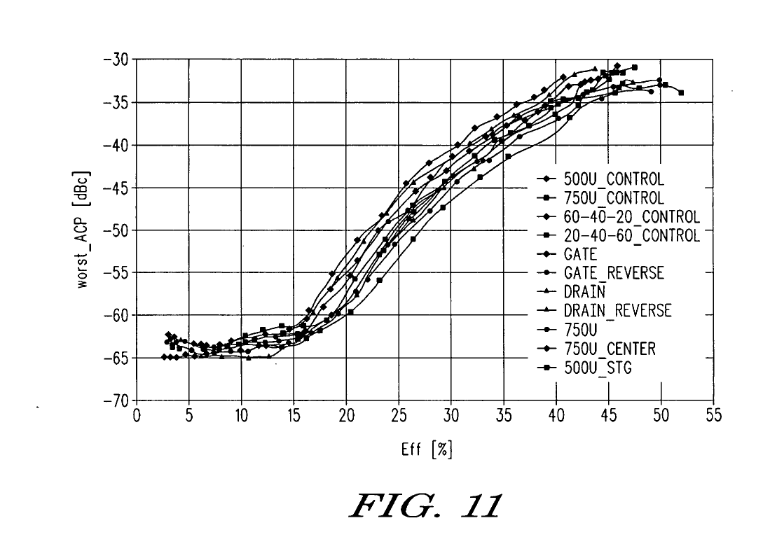

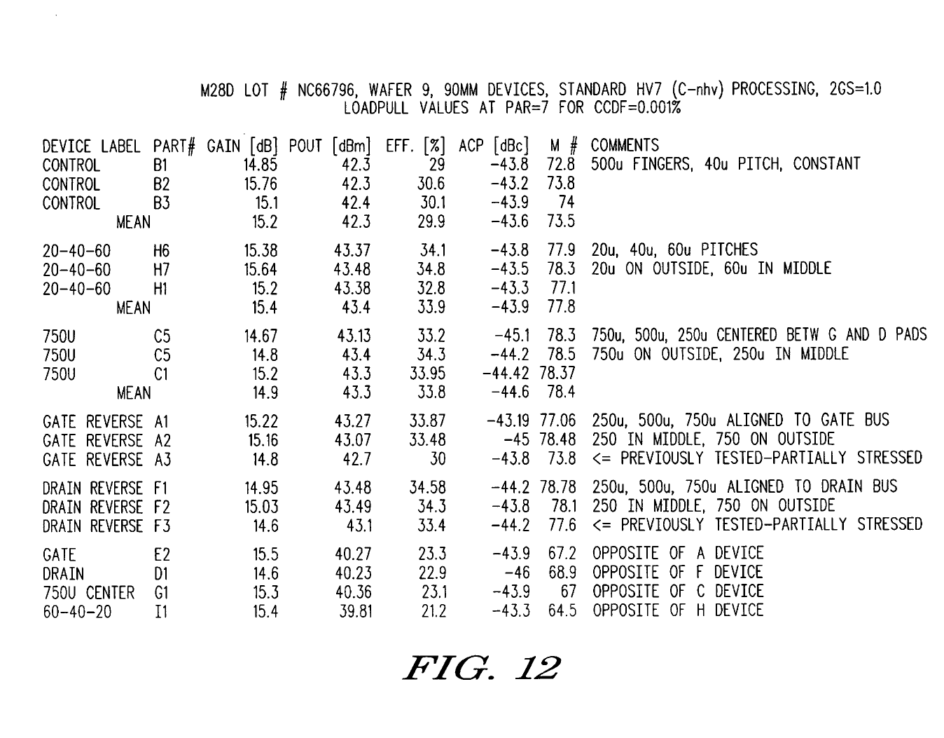

FIG. 11 is a graphical view of RF performance characteristics for transistors having 60 mm total gate width (i.e., aggregate sum of individual gate widths) and layouts of FIGS. 2-10. The RF results of FIG. 11 include a plot of worst Adjacent Channel Power (ACP) in units of dBc versus Efficiency in units of percent. Select cells from an analysis of 60 mm total gate width devices were measured using a most recent comparison method (e.g., 7 dB Peak-to-Average Ratio (PAR), “near” max power tuning, etc.). FIG. 12 is a table view of RF performance characteristics for a number of transistors having 90 mm total gate widths and layouts of FIGS. 2-10. As can be understood from the graphical view of FIG. 11 and the table view of FIG. 12, a number of alternate layouts of various combinations of distinct single finger (unit cell) designs were tested. Two transistor sizes that were evaluated include 60 mm total gate width and 90 mm total gate width devices. Equivalent layouts for both the 60 mm and 90 mm total gate width devices were tested. Evaluations were performed on single, unmatched die using RF loadpull measurement techniques. High power (43.3 dBm) with good efficiency (33.8%) and high performance metric (M# or FOM(Figure of Merit)) (77.8) were noted for very wide die (approx. 7530 μm). Furthermore, it is noted that 3 points efficiency increase or 4 points performance metric (M#) increase could be the difference between technology platform generations. The performance metric M# is a combination of efficiency and ACP. In summary, those layouts with more power or power density contribution from ends of the overall transistor die rather that the middle of the respective die performed significantly better than layouts of opposite configuration, and better than a conventional layout. Additional investigation can be used to quantify die behavior in 2-up (two separate die in parallel packages) configured with internal input and output impedance matching circuits.

The embodiments of the present disclosure advantageously facilitate scaling to higher power, larger RF transistors, while reducing “combining” losses usually accompanying scale-up. The embodiments of the present disclosure also advantageously provide for improved efficiency and linearity for an LDMOS transistor platform. Furthermore, the embodiments of the present disclosure advantageously provide for a next generation product platform performance by re-configuring transistor layout designs according to the embodiments of the present disclosure. By reducing performance losses as overall RF transistor size becomes larger, the net effect is the same as improving the technical performance of existing RF transistor finger elements. Accordingly, a layout geometry change as disclosed herein provides for improved transistor performance (for very low cost) that must otherwise come from intrinsic transistor processing improvements (at much higher cost).

By now it should be appreciated that there has been provided an RF transistor device having variable size “finger” widths and/or spacings incorporated within a single transistor device. Such an RF transistor that includes the use of variable topologies within the same device is suitable for an RF power amplifier part.

By now it should be further appreciated that there has been provided an RF power transistor featuring a variable topology layout comprises a number of groups of gate fingers of various widths, wherein the groups of gate fingers includes both uniform and non-uniform pitches. The RF power transistor further includes wherein the widths include any number of different widths. In addition, in another embodiment, there are included three widths W1, W2, and W3, in which W3>W2>W1.

In other embodiments, the groups of gate fingers are arranged from greater width to lesser width disposed from a periphery to a center of the device. The gate fingers can also be configured to have one of a centered justification, a gate pad side justification, and a drain pad side justification, along a dimension of the power transistor layout. Still further, the groups of gate fingers having widths W1, W2, and W3 can be configured symmetrically about a center line of the device. In another embodiment, the variable gate finger widths provide a level of greater power density at the outside of the die in relation to a power density at the center of the die.

In another embodiment, the gate finger widths are configured in an asymmetrical arrangement about a center line of the device. In addition, the gate finger widths can be configured in one or more asymmetrical arrangements. Furthermore, in another embodiment, the groups of gate fingers are arranged from greater width to lesser width disposed from a periphery to a center of the device, and further wherein the gate finger widths are configured in an asymmetrical arrangement about a center line of the device.

In another embodiment, a method of making an RF power transistor featuring a variable topology layout comprises: forming a number of groups of gate fingers of various widths, wherein the groups of gate fingers includes both uniform and non-uniform pitches. The method can include wherein the widths include any number of different widths. In addition, the method can further comprise including three widths W1, W2, and W3, in which W3>W2>W1. In another embodiment, the method can further comprise: arranging the groups of gate fingers from greater width to lesser width disposed from a periphery to a center of the device. The method can also further comprise: configuring the gate fingers to have one of a centered justification, a gate pad side justification, and a drain pad side justification, along a dimension of the power transistor layout. In another embodiment, the method further comprises: configuring the groups of gate fingers having widths W1, W2, and W3 symmetrically about a center line of the device. The variable gate finger widths provide a level of greater power density at the outside of the die in relation to a power density at the center of the die.

According to another embodiment, the method further comprises: configuring the gate finger widths in an asymmetrical arrangement about a center line of the device. In addition, the method further comprises: configuring the gate finger widths in one or more asymmetrical arrangements. Still further, the method can comprise arranging the groups of gate fingers from greater width to lesser width disposed from a periphery to a center of the device; and configuring the gate finger widths in an asymmetrical arrangement about a center line of the device.

Because the apparatus implementing the present invention is, for the most part, composed of transistor components known to those skilled in the art, certain transistor details will not be explained in any greater extent than that considered necessary as illustrated above, for the understanding and appreciation of the underlying concepts of the present invention and in order not to obfuscate or distract from the teachings of the present invention.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

It is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Although the invention is described herein with reference to specific embodiments, various modifications and changes can be made without departing from the scope of the present invention as set forth in the claims below. For example, the embodiments of the present disclosure can be used to provide performance increases in specific RF transistor devices without requiring new platform technology development to be implemented first. In addition, while a 2-dimensional layout has been described herein, the embodiments may also be applicable to 3-dimensional structures and associated designs. Furthermore, the embodiments may be applicable to future generations of RF-LDMOS devices, as well as, other RF transistor designs that use silicon but not LDMOS or that use non-silicon technologies. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. An RF power transistor featuring a variable topology layout comprising:
a number of groups of gate fingers of various widths, wherein the groups of gate fingers includes both uniform and non-uniform pitches.

2. The RF power transistor of claim 1, wherein the widths include any number of different widths.

3. The RF power transistor of claim 2, wherein there are included three widths W1, W2, and W3, in which W3>W2>W1.

4. The RF power transistor of claim 1, wherein the groups of gate fingers are arranged from greater width to lesser width disposed from a periphery to a center of the device.

5. The RF power transistor of claim 1, wherein the gate fingers are configured to have one of a centered justification, a gate pad side justification, and a drain pad side justification, along a dimension of the power transistor layout.

6. The RF power transistor of claim 1, wherein the groups of gate fingers having widths W1, W2, and W3 are configured symmetrically about a center line of the device.

7. The RF power transistor of claim 1, wherein the variable gate finger widths provide a level of greater power density at the outside of the die in relation to a power density at the center of the die.

8. The RF power transistor of claim 1, wherein the gate finger widths are configured in an asymmetrical arrangement about a center line of the device.

9. The RF power transistor of claim 1, wherein the gate finger widths are configured in one or more asymmetrical arrangements.

10. The RF power transistor of claim 1, wherein the groups of gate fingers are arranged from greater width to lesser width disposed from a periphery to a center of the device, and further wherein the gate finger widths are configured in an asymmetrical arrangement about a center line of the device.

11. A method of making an RF power transistor featuring a variable topology layout comprising:
forming a number of groups of gate fingers of various widths, wherein the groups of gate fingers includes both uniform and non-uniform pitches.

12. The method of claim 11, wherein the widths include any number of different widths.

13. The method of claim 12, further comprising:
including three widths W1, W2, and W3, in which W3>W2>W1.

14. The method of claim 11, further comprising:
arranging the groups of gate fingers from greater width to lesser width disposed from a periphery to a center of the device.

15. The method of claim 11, further comprising:
configuring the gate fingers to have one of a centered justification, a gate pad side justification, and a drain pad side justification, along a dimension of the power transistor layout.

16. The method of claim 11, further comprising:
configuring the groups of gate fingers having widths W1, W2, and W3 symmetrically about a center line of the device.

17. The method of claim 11, wherein the variable gate finger widths provide a level of greater power density at the outside of the die in relation to a power density at the center of the die.

18. The method of claim 11, further comprising:
configuring the gate finger widths in an asymmetrical arrangement about a center line of the device.

19. The method of claim 11, further comprising:
configuring the gate finger widths in one or more asymmetrical arrangements.

20. The method of claim 11, further comprising:
arranging the groups of gate fingers from greater width to lesser width disposed from a periphery to a center of the device; and
configuring the gate finger widths in an asymmetrical arrangement about a center line of the device.
